(19) United States
(12) Patent Application Publication
(10) Pub. No.: US 2003/0233612 A1
(43) Pub. Date: Dec. 18, 2003

(54) Method for providing MTP-2 services in common channel communications

(76) Inventors: Seamus G. Gilchrist, Mt. Laurel, NJ (US); John C. Curtis, Spring Lake Heights, NJ (US); Barry Nagelberg, Cherry Hill, NJ (US); Heinz Prantner, Mt. Laurel, NJ (US)

Correspondence Address: FLESHNER & KIM, LLP, P.O. Box 221200, Chantilly, VA, 20153-1200, US

(21) Appl. No.: 10/425,991

(22) Filed: Apr. 30, 2003

Related U.S. Application Data
(63) Continuation of application No. 10/420,847, filed on Apr. 23, 2003.
Application No. 10/420,847 is a continuation of application No. PCT/US01/32599, filed on Oct. 23, 2001.
(60) Provisional application No. 60/242,178, filed on Oct. 23, 2000.
(60) Provisional application No. 60/242,420, filed on Oct. 24, 2000.
(60) Provisional application No. 60/247,015, filed on Nov. 13, 2000.
(60) Provisional application No. 60/251,789, filed on Dec. 8, 2000.
(60) Provisional application No. 60/267,137, filed on Feb. 8, 2001.
(60) Provisional application No. 60/297,758, filed on Jun. 14, 2001.

(51) Int. Cl. H03M 13/00

(52) U.S. Cl. 714/776

(57) ABSTRACT

A common channel signaling system is disclosed that communicates Signaling System Number 7 (SS7) signaling information between two SS7 Signaling Points (SPs) through a packet-switched network. The preferred embodiment of the system includes at least two SS7 SPs and two Signaling Gateways (SGs). Each SG communicates SS7 signaling information with a separate one of the two SS7 SPs through a dedicated circuit. The two SGs intercommunicate with each other through a packet switched network. Additionally, the two SS7 SPs communicate the SS7 signaling information between each other through the two dedicated circuits, the two SGs, and the packet switched network. The common channel signaling data is for transmission over a packet switched network and is then transmitted to a received SG. The receiving SG receives the common channel signal data therefrom.

### BACKGROUND OF THE INVENTION

This application is a Continuation of U.S. patent application Ser. No. 10/420,847, filed Apr. 23, 2003, which claims priority to International Application No. PCT/US01/32599, filed Oct. 23, 2001, and claims priority to U.S. Provisional Application Serial No. 60/242,178, filed Oct. 23, 2000; No. 60/242,420, filed Oct. 24, 2000; No. 60/247,015, filed Nov. 13, 2000; No. 60/251,789, filed Dec. 8, 2000; No. 60/267,137, filed Feb. 8, 2001; and No. 60/297,758, filed Jun. 14, 2001, whose entire disclosure is incorporated herein by reference.

1. Field of the Invention

The present invention relates to common channel signaling and, more particularly, to providing Signaling System No. 7 (SS7) communication over a packet-based network.

2. Background of the Related Art

A common channel network, such as a SS7 network, is separate from the bearer channel network, and supports the bearer channel network. The common channel network consists of various signaling points that provide functions for the signaling. Among these signaling points are the Service Switching Point (SSP), the Signal Transfer Point (STP), and the Signal Control Point (SCP). Signaling End Point (SEP) refers to any element which does not have STP capability. Signaling Point (SP) refers to any element within the SS7 network that has SS7 MTP 3 Level capabilities and may be addressed as an SS7 network element. It should be noted that other SPs exist such as the Intelligent Peripheral. These SPs are identical in nature, with respect to their behavior, as other SPs.

The SSPs, which are typically end points of the SS7 network, generally use calling party information, such as dialed digits, to determine how to route a call. This function is associated with the set-up and tear-down of inter-switch voice trunks. Thus, the SSPs create signal packets having appropriate addressing information. The SSPs also send messages to external data bases. Typically, these messages contain queries to these remote shared databases concerning call routing.

The SCP provides an interface to database applications. The SSPs originate messages to SCPs to receive routing instructions. Thus the SCP provides access to various database applications. That is, the SCP is typically the front end SS7 component to a database system.

The STPs are typically configured between SSP end points. Thus the STP is used to switch and route SS7 messages. That is, the STPs allow packets to be passed from one signaling end point to another signaling end point or signaling control point. In the US network hierarchy STPs are always deployed as stand-alone network elements in mated pairs for redundancy. In other national networks SSPs might include STP functionality and might or might not be part of a pair.

FIG. 1A illustrates a related art SS7 signaling system. As shown in FIG. 1, Signaling Points (SPs) 1, 2 communicate SS7 signaling information through a circuit switched signaling link 3. The SPs 1, 2 can be a network element such as a SSP, SCP or STP. The signaling link 3 is a dedicated circuit used to communicate information needed to establish, maintain, and tear down individual switched circuits to carry voice and data traffic between the two SPs 1, 2. A typical network contains many SPs that are each interconnected with a plurality of other SPs by one or more dedicated circuits. Although each dedicated circuit may support the operation of many thousands of voice circuits, a large number of dedicated circuits are required nevertheless. The dedicated circuits themselves do not carry any voice traffic, but support the creation and elimination of switched voice circuits.

FIG. 1B illustrates a related art system for transporting SS7 signaling messages over a packet switched network. As shown in FIG. 1B, SP 1 is coupled to signaling gateway 8a by a dedicated circuit 3a. Signaling gateway 8a is designated with point code A, and transmits the signaling data over the Internet to the destination signaling gateway 8b. Signaling gateway 8b is designated with point code B, and is coupled to the destination SP 2 by a dedicated circuit 3b. Thus, each signaling gateway 8a, 8b is designated with a static point code to make transmission over the Internet possible.

The related art SS7 system has various problems. Additionally, it requires that the other end of the link be a MGC or other switch that has been enhanced with the IP/SCTP/M2UA protocol, which is relatively uncommon. That means that there is a large market which has not been addressed (ie., the existing infrastructure). For example, only a small portion of the dedicated circuit's potential capacity is typically used. Due to the high cost of installing, maintaining, and operating the dedicated circuits, their inefficient use unnecessarily increases the cost of providing the voice circuit to the end user.

Additionally, the requirement for dedicated circuits reduces the flexibility of the overall system. The circuit order placement often results in significant delays for the rollout of a service. As a result, the networks are generally very static and not often reconfigured.

The following references are hereby incorporated by reference into the specification: ITU-T Recommendation Q.700, “Introduction To ITU-T Signaling System No. 7 (SS7)”; ITU-T Recommendation Q.701-Q.705, “Signaling System No. 7 (SS7)—Message Transfer Part (MTP)”; ANSI T1.111 “Signaling System Number 7—Message Transfer Part”; Bellcore GR-246-CORE “Bell Communications Research Specification of Signaling System Number 7,” Volume 1, December 1995; Framework Architecture for Signaling Transport, draft-ietf-sigtran-framework-arch-03.txt, June 1999; Stream Control Transmission Protocol, IETF RFC 2960, October 2000; Media Gateway Control Protocol (MGCP), draft-huitema-megaco-mgcp-v1-03.txt, August 1999; ITU-T Recommendation Q.2210, “Message Transfer Part Level 3 Functions and Messages Using the Services of ITU-T Recommendation Q.2140”; RFC 2196, “Site Security Handbook,” B. Fraser Ed., September 1997; RFC 2401, “Security Architecture for the Internet Protocol,” S. Kent, R. Atkinson, November 1998.

### SUMMARY OF THE INVENTION

An object of the present invention is to solve at least the above problems and disadvantages and to provide at least the advantages described hereinafter.

Another object of the present invention is to provide a protocol and an Open System Interconnection (OSI) Layer 2 filtering, error monitoring, and forwarding function for the transparent transport and proxy of Signaling System No. 7 (SS7) Message Transfer Part Level-2 (MTP-2) user signaling messages over a packet switched network.

Another object of the invention is to provide the transparent transport of SS7 signaling traffic between two MTP-2s over a packet switched network, such as an IP network.

Another object of the invention is to provide the transparent transport and proxy of SS7 MTP-2 user signaling messages over an Internet Protocol (IP) using a Stream Control Transmission Protocol (SCTP).

Another object of the invention is to provide convergence of some signaling and data networks.

Another object of the invention is to provide a Switched Circuit Network (SCN) signaling protocol delivery between two Signaling Gateways (SGs), each with a SS7 signaling link connection to a signaling point, that provides the appearance of a single signaling link between the two signaling points.

Another object of the invention is to provide the transparent transport of SS7 signaling traffic between two Message Transport Part Layer 2 (MTP-2) without modifying the existing SS7 infrastructure.

Another object of the invention is to provide the transparent transport of SS7 signaling traffic between two MTP-2s that (a) requires minimum resources on the gateway; (b) filters redundant and unnecessary MTP-2 messages from the SCTP association; (c) monitors both Signal Unit and Alignment Errors and takes the link out of service when these monitors indicate; (d) generates the appropriate MTP-2 messages from the SG to the SS7 signaling point; and (e) supports the management of active associations between the SGs.

Another object of the invention is to provide common channel signaling over a packet switched network without modifying the existing SS7 infrastructure.

Another object of the invention is to provide the signaling gateway, including a common channel interface configured to communicate common channel signaling information with a signaling point, a Nodal Interworking Function (NIF), communicatively coupled to the common channel interface and configured to convert common channel signaling information from a common channel protocol to a packet switched network protocol, and a packet switched network interface coupled to the NIF and configured to communicate packet switched network protocol information to a packet switched network.

Another object of the invention is to provide a method of converting Signaling System No. 7 (SS7) signaling information into a packet switched network protocol, including receiving SS7 signaling information from a common channel signaling point by a SS7 interface of an originating Signaling Gateway (SG) having no point code, converting the SS7 signaling information from a common channel protocol into the packet switched network protocol, and transmitting the converted signaling information over a packet switched network protocol to a destination SG having no point code.

Another object of the invention is to provide a common channel signaling system, including first and second common channel Signaling Points (SPs), and first and second point code free Signaling Gateways (SG), the first SG being coupled to the first SP by a first dedicated circuit and the second SG being coupled to the second SP by a second dedicated circuit, wherein each SG is configured to convert common channel signaling information received from the corresponding SP into a packet switched network protocol and transmit the converted signaling information over a packet switched network to the other SG to provide common channel signaling. As used herein, point code free means that the signaling gateways have no point codes.

To achieve at least the above objects in whole or in parts, there is provided a signaling gateway having a Signaling System No. 7 (SS7) interface that communicates SS7 signaling information, a packet switched network interface that communicates information in a packet switched network format, and a Nodal Interworking Function (NIF) communicatively coupled to the SS7 interface and the packet switched network interface. The SS7 interface, the packet switched network interface, and the NIF convert SS7 signaling information to packet switched network format information and convert received information in the packet switched network format to SS7 signaling information. Additionally, the signaling gateway does not include a point code, since it is not required.

To achieve at least the above objects in whole or in parts, there is further provided a method of converting SS7 signaling information into a packet switched network protocol with a signaling gateway (SG) having no point code, including receiving the SS7 signaling information with a SS7 interface of the SG, converting the SS7 signaling information into a packet switched network format using a NIF of the SG, and conveying the converted signaling information to a packet switched network interface of the SG.

To achieve at least the above objects in whole or in parts, there is further provided a signaling system having two SS7 signaling points (SPs) and two SGs having no point codes. Each of the two SGs preferably communicates the SS7 signaling information with a separate one of the two SPs through a dedicated circuit, and the two SGs communicate with each other through a packet switched network. The two SPs preferably communicate the SS7 signaling information between each other through the two dedicated circuits, the two SGs, and the packet switched network.

To achieve at least the above objects in whole or in parts, there is further provided a SG having a SS7 interface, a packet switched network interface, and a NIF that interfaces the SS7 interface and the packet switched network interface. The NIF converts SS7 signaling information to a packet switched network format and converts packet switched protocol data to SS7 format so that SS7 signaling messages can be transmitted between the two SGs over by a packet switched network. Each SG also has no point code, and is connected to a corresponding SP by a dedicated circuit.

To achieve at least the above objects in whole or in parts, there is further provided a method of communicating SS7 signaling information across a packet switched network, including converting SS7 protocol signaling information received by a first SG to a packet switched network protocol with a NIF of the first SG; communicating the packet switched network protocol SS7 signaling information from the first SG to a second SG through a packet switched network; and converting the packet switched network protocol SS7 signaling information to the SS7 protocol with the NIF of the second SG.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The preferred embodiments of the invention will be described in detail with reference to the following drawings in which like reference numerals refer to like elements wherein:

FIG. 1A illustrates a related art SS7 signaling system;

FIG. 1B illustrates a related art SS7 signaling system that employs a packet switched network;

FIG. 2 illustrates a SS7 signaling link between two SPs provided in part by a packet switched network, according to the preferred embodiment;

FIG. 3A illustrates a MTP-2 transparent transport architecture, according to the preferred embodiment;

FIG. 3B illustrates a preferred embodiment of the SG's MTP-2 transparent transport architecture illustrated in FIG. 3A;

FIG. 4 illustrates a physical network architecture relevant to carrier-grade operation in the IP network domain, according to the preferred embodiment;

FIG. 5 illustrates a common message header used among all signaling protocol adaptation layers according to a preferred embodiment;

FIG. 6 illustrates a variable length parameter format of the M2TP message according to a preferred embodiment;

FIG. 7A shows a preferred embodiment of a data message;

FIG. 7B illustrates a second embodiment of a data message;

FIG. 8 illustrates a signaling gateway message (SGM) communicated by the SGs at each end of a SS7 virtual link according to a preferred embodiment;

FIG. 9 illustrates the format for the SG-DN message parameters according to a preferred embodiment;

FIG. 10 illustrates the format for the HEARTBEAT message according to a preferred embodiment;

FIG. 11 illustrates the format for the error message according to a preferred embodiment;

FIG. 12 illustrates an exemplary M2TP message flow for the establishment of traffic between two mated SGs according to a preferred embodiment; and

FIG. 13 illustrates the state machine maintained by the SG for each SS7 virtual link segment to a peer SG according to a preferred embodiment.

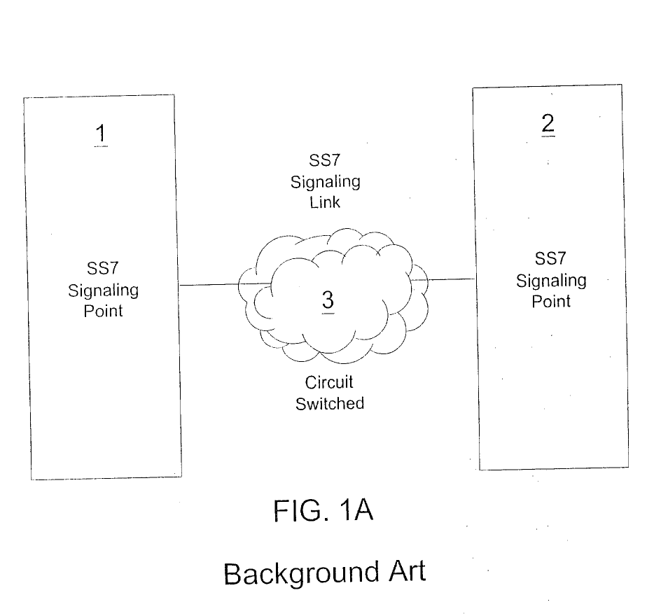

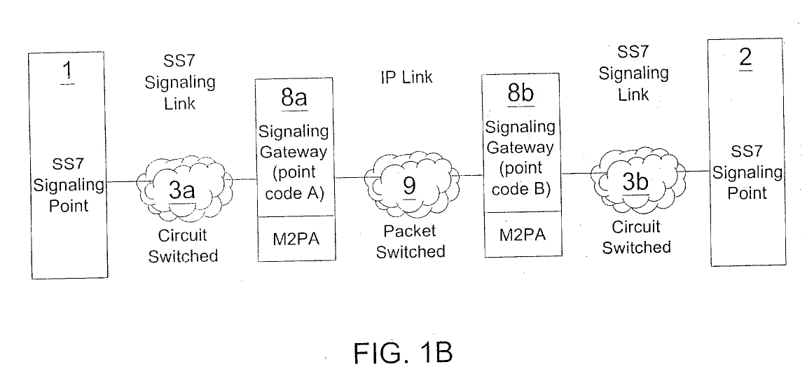

### DETAILED DESCRIPTION OF PREFERRED EMBODIMENTS

The present invention increases the efficiency of circuits used to communicate SS7 signaling information between Signaling Points (SPs). The SPs could be Signaling End Points (SEPs), Signaling Transfer Points (STPs), or any other signaling point. According to the preferred embodiment, a packet switched network communicates SS7 signaling information over a significant portion of the communication link between the SPs. Because legacy SS7 SPs do not have a signaling interface that is compatible with a packet switched network, a Signaling Gateway (SG) associated with each SP provides this feature. That is, the SG receives the SS7 signaling messages, and protocol processes them for transport over a packet switched network. A receiving SG then receives the protocol processed signaling messages and converts them back to the original SS7 signaling messages. Moreover, according to the preferred embodiment, the SGs do not include point codes. Thus, the signaling information is transparently passed between the Signaling Points. Throughout this description, it is assumed that any reference to a SG of the preferred embodiment relates to a SG without a point code.

The framework architecture that has been defined for Switched Circuit Network (SCN) signaling transport over IP uses multiple components, including SCTP and a SCN adaptation module to support the services expected by a particular SCN signaling protocol from its underlying protocol layer. Within this framework architecture, this disclosure describes a SCN adaptation module that is suitable for the transport of SS7 MTP Level 2 (MTP-2) user messages from one SG to a peer SG. The M2TP preferably uses SCTP as the underlying reliable signaling transport protocol.

The SG preferably communicates with its associated SP through a dedicated circuit switched link and communicates with all other SGs through a packet switched network. Ideally, the length of the dedicated circuit between each SP and its associated SG is minimized, and the packet switched network is used to communicate the signaling information over most of the distance between the communicating SPs.

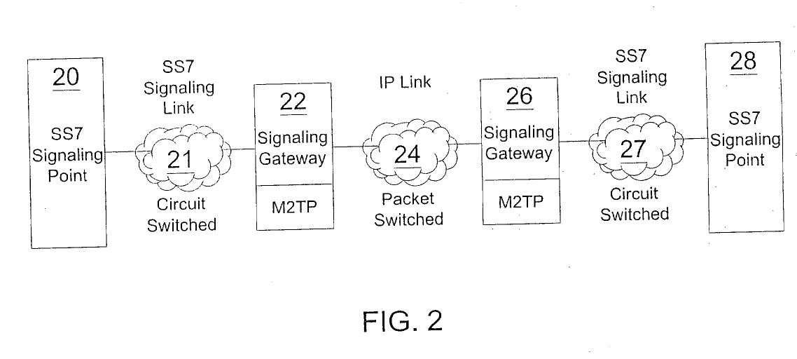

FIG. 2 illustrates a SS7 signaling link between two SPs 20, 28 according to a preferred embodiment of the invention. The signaling link between the SPs 20, 28 is provided in part by a packet switched network 24. Each SP 20, 28 has an associated SG 22, 26 with which it communicates signaling information by way of a corresponding circuit switched dedicated link 21, 27. Each of the SGs 22, 26 includes a MTP-2 transport proxy function (M2TP), which allows for communicating Layer 2 data between the two SEPs 20, 28 over a packet switched network 24. The layer 2 data is preferably MTP-2 data. Thus, as shown in FIG. 2, the SPs 20, 28, in association with the SGs 22, 26, are able to communicate signaling information over the packet switched network 24.

This architecture allows the SS7 link between two SPs 20, 28 to be transparently replaced with a packet based network 24. Thus, the SGs 22, 26, which each have a dedicated SS7 signaling link 21, 27 connection to a SP 20, 28 (such as a Public Switched Telephone Network (PSTN) switch), provide the appearance of a single dedicated SS7 link between the two switches. Each SG 22, 26 preferably communicates SS7 signaling messages with the corresponding SP 20, 28 by standard SS7 interfaces using the SS7 Message Transfer Part (MTP). The MTP-2 protocol associated with the SGs is preferably a slimmed down version of the MTP-2 layer. It should be understood, however, that the same process could be carried out using a full MTP-2 protocol stack as an alternative embodiment. By using the full MTP-2 protocol stack, the SG could provide for full termination.

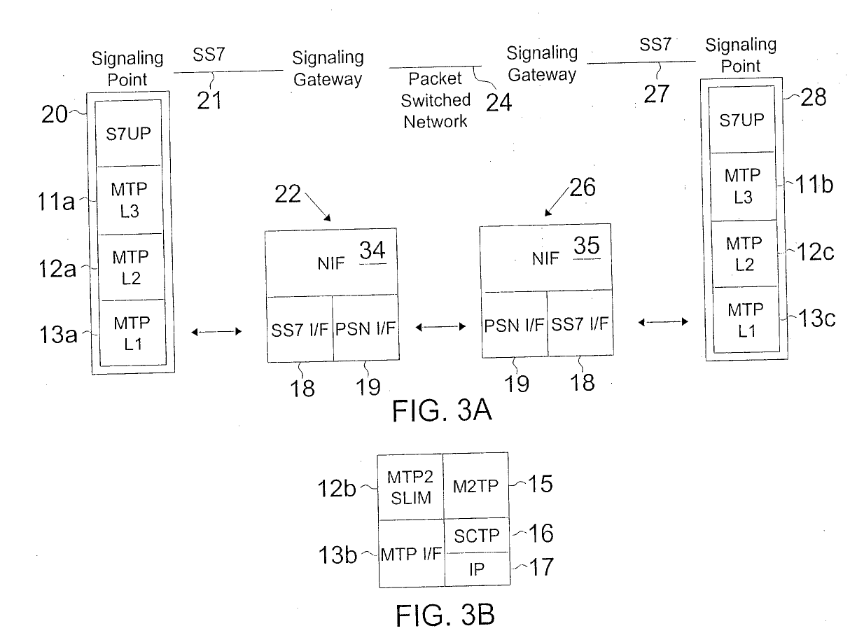

FIG. 3A illustrates the protocol structure for transporting common channel signaling data over a packet switched network according to a preferred embodiment. Referring to FIG. 3A, SP 20 is coupled to a Nodal Interworking Function (NIF) 34 of the SG 22 by a dedicated SS7 link segment 21. NIF 34 is coupled to a second NIF 35 over a packet switched network 24. The second NIF 35 is coupled to a SP 28 by a dedicated SS7 link segment 27. According to the preferred embodiment, each NIF 34, 35 encapsulates the SS7 signaling data into M2TP formatted packets for transport over a packet switched network 24. Each NIF 34, 35 also receives the packets of data from the packet switched network 24 and processes the packets into SS7 signaling message format.

SS7 signaling messages are communicated between the SPs 20, 28 at the MTP-2 layer 12. An originating SG 22 receives a communication from a corresponding SP 20 over the circuit switched link 21. The originating SG 22 then interprets the signaling messages using NIF 34, and converts the message to a communication protocol compatible with the packet switched network. The destination SG 26 receives the signaling message from the originating SG 22, via the packet switched network 24. NIF 35 of the destination SG 26 converts, the received message back to the SS7 protocol communicated by the originating SP 20. Thereafter, the destination SG 26 communicates the SS7 signaling message to the destination SP 28 through the circuit switched link 27.

Each NIF 34, 35 also preferably includes an Alignment Error Rate Monitor (AERM) and a Signal Unit Error Date Monitor (SUERM). The AERM and SUERM monitor the signaling link performance, and disable the link if a specific performance level is not maintained. The disabling of the link is made by sending a control packet on the M2TP connection to the remote SG which then takes the link between itself and its associated SP out of service. It does this by sending a link stop message to the MTP Level 2 which then sends signal units of type SIOS to the SP.

The combined set of SGs 22, 26 communicating over the packet switched network 24 thus appears to each SP 20, 28 as a single, dedicated SS7 signaling link. Each SG 22, 26 also preferably either filters out redundant messages, such as redundant Fill-In Signal Units (FISUs) and Link Status Signal Units LSSUs. Alternatively, the SG 22 could forward redundant messages to its peer SG 26, or regenerate the appropriate SU based on the forwarded messages from the mated SG 26. It should be understood that the SPs 20, 28 could be SSPs, SCPs, STPs or other SS7 end points.

FIG. 3B illustrates a preferred embodiment of the MTP-2 transparent transport architecture for each SG 22, 26. As shown in FIG. 3B, each SG 22, 26 preferably includes a MTP level 1 (MTP-1) layer 13b configured to interface with a corresponding layer of a SP 20, 28. Additionally, Stream Control Transmission Protocol (SCTP) 16 and Internet Protocol (IP) 17 layers are provided to interface with the packet switched network. Next, a MTP-2 layer 12b is provided for interfacing with the MTP-2 layer 12a, 12c of the SP 20, 128. This MTP-2 layer 12b is preferably a slimmed-down version of the MTP-2 layer. The slimmed-down version of the MTP-2 layer would not provide a local acknowledgement for signal units for example. Finally, a M2TP layer 15 is provided to provide a protocol for transporting MTP-2 protocol messages between the two SPs 20, 28 over the packet switched network 24.

The SS7 MTP-1 layer 13a and the NIF 34 of the originating SG 22 preferably provide reliable transport of the MTP Level 3 (MTP-3) user signaling messages (both control messages in the form of network management messages and data in the form of user application part messages such as SCCP, TCAP or ISUP) to and from SP 20. Each NIF 34, 35 preferably has a slimmed-down MTP-2 layer 12b that communicates with the MTP-1 layer 13b and a M2TP layer 15 that communicates with the SCTP layer 16. Together, the slim MTP-2 12b and M2TP 15 translate signaling messages between the SS7 signaling protocol and the packet switched network protocol to support the transparent transport of SS7 signaling messages through the packet switched network 24.

SGs 22, 26 thus support the transport of MTP-2 user signaling traffic received from the originating SP 20 to the destination SP 28, providing the appearance of an uninterrupted signaling link. Because, however, the M2TP layer 15 provides no local acknowledgment (i.e., all acknowledgments are provided from the remote signaling end point) and the SG 22, 26 does not modify the Backward Sequence Number (BSN) fields or MTP-2 timer functions, the M2TP layer 15 does not intervene in detecting, or recovering from, protocol related link problems.

The MTP-2 12b layer of each SG 22, 26 provides Alignment Error Rate Monitoring (AERM) and Signal Unit Error Rate Monitoring (SUERM) and takes the link out of service as required to meet the signaling link performance criteria. Additionally, the network is preferably designed such that the SCTP 16 link delivers low loss (preferably, 1 M2TP packet loss per 10¹² packets) and low latency (preferably below 10 mS) to ensure that sub-optimal SCTP performance does not impact synchronization of SS7 link states between SPs 20, 28.

To meet the stringent SS7 signaling reliability and performance requirements for carrier grade networks, there is preferably no single point of failure provisioned in the end-to-end network architecture between the two SPs 20, 28. Depending on the reliability of each SG 22, 26, such requirements can typically be met by spreading links in a link set across multiple SG pairs, and providing redundant Quality of Service (QoS)-bounded packet switched network paths for SCTP associations between SCTP end points. Signaling network reliability is provided through the capabilities of the SS7 MTP-2 and MTP-3 protocols, as currently defined in the relevant standards. MTP-2 retransmission is thus relegated to the SPs 20, 28 and not to the SGs 22, 26.

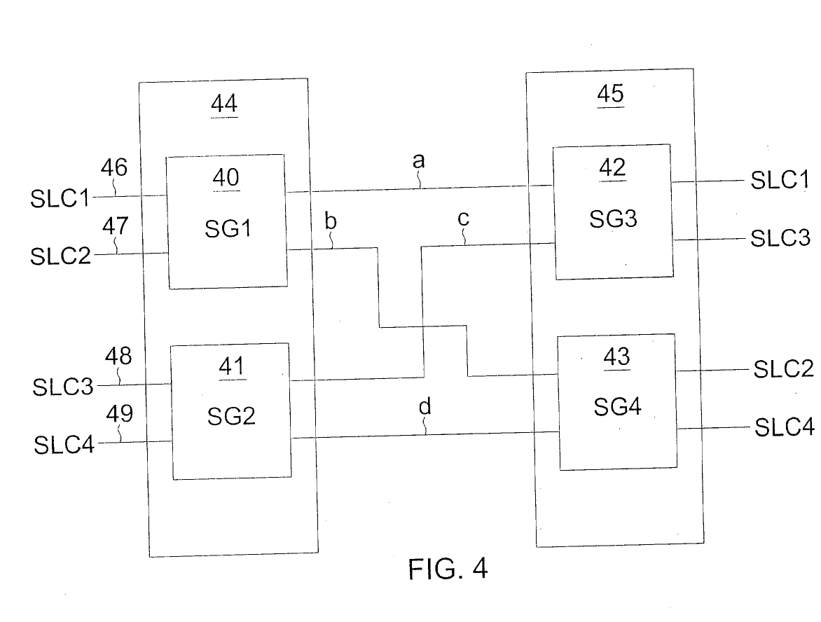

FIG. 4 illustrates a physical network architecture relevant to carrier-grade operation in the IP network domain. Carrier grade network reliability is provided through the existing SS7 mechanisms. As shown in FIG. 4, SGs 40, 41, 42, 43 are preferably deployed in SG pairs, 44, 45. Link sets are spread across both SGs 40, 41 and 42, 43 of the pair. Four Signaling Link Codes (SLCs) 46-49 are part of the same SS7 link set, and are identical on both segments of the SS7 link. Thus, SLC1 46 terminates at SG1 40 and SG3 42, SLC2 47 terminates at SG1 40 and SG4 43, SLC3 48 terminates at SG2 41 and SG3 42, and SLC4 49 terminates at SG2 41 and SG4 43. This configuration prevents a loss of signaling traffic between two signaling points, in the event a single SG 40-43 fails. The SCTP 16 (and User Datagram Protocol (UDP)/Transmission Control Protocol (TCP)) registered user port number assignment for M2TP is 99 (noting that this is not an official port assignment number. Each of the SGs 40-43 is configured to protocol process the SS7 data in accordance with M2TP. The protocol processed data is then sent from one SG pair 44 to the other SG pair 45 over the communication paths a, b, c, d. Signaling paths a, b, c, d comprise a packet switched network, such as an IP network.

FIGS. 5-11 illustrate preferred protocol elements for M2TP formatted messages. The general M2TP message format preferably includes a common message header, followed by zero or more variable length parameters as defined by the message type. For forward compatibility, all message types may have attached parameters even if none are specified in a prior version. All fields in a M2TP message are preferably transmitted in the network byte order, unless otherwise stated. Where more than one parameter is included in a message, the parameters may be in any order.

FIG. 5 illustrates a preferred format of the common message header 50 used among all signaling protocol adaptation layers. The protocol messages for MTP-2 user adaptation require a message structure that preferably contains a version field 51, a reserved field 52, a message class field 53, a message type 54, a message length field 55, and message contents.

The version field 51 is preferably 8 bits, and contains the version of the M2TP adaptation layer. The supported version is Release 1.0 0×1. The reserved field 52 is preferably 8-bits, and is preferably set to all “0”s. This field is ignored by the receiver and is reserved for future use. The message class field 53 contains an 8-bit unsigned integer value that indicates a message class. Table 1 shows the valid message classes and the associated integer.

TABLE 1

| Value | Description |
|---|---|
| 0 | Management (MGMT) Message |
| 1-2 | Reserved |
| 3 | SG State Maintenance (SGM) Messages |
| 4-5 | Reserved |
| 6 | MTP-2 User Adaptation (MAUP) |
| 7 | Reserved |
| 8 | Reserved |
| 9 | Reserved |
| 10 | Data Messages |
| 11-55 | Reserved |

The message type field 54 indicates the message type for each of the three defined message classes. Table 2 shows the MTP-2 Tunneling Protocol (M2TP) message types. Table 3 shows the Signaling Gateway State Maintenance (SGM) message types. Table 4 shows the Management (MGMT) message types.

TABLE 2

| Value | Description |
|---|---|
| 0 | Reserved |
| 1 | Data |
| 2 to 255 | Reserved for M2TP Messages |

TABLE 3

| Value | Description |
|---|---|
| 0 | Reserved |
| 1 | SG Up (UP) |
| 2 | SG Down (DOWN) |
| 3 | Heartbeat (BEAT) |
| 4 | SG Up Ack (UP ACK) |
| 5 | SG Down Ack (DOWN ACK) |
| 6 | Heartbeat Ack (BEAT ACK) |
| 7 to 255 | Reserved for SGM Messages |

TABLE 4

| Value | Description |
|---|---|
| 0 | Error (ERR) |
| 1 to 255 | Reserved for Management Messages |

The message length field 55 defines the length of the message in octets, including the header 50. For messages with a final parameter containing padding, the parameter padding is preferably included in the message length. It is noted that a receiver should accept the message regardless of whether the final parameter padding is included in the message length.

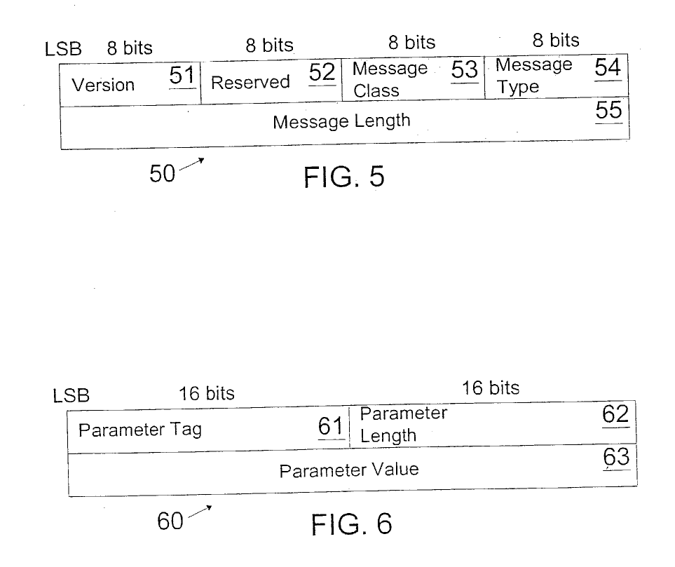

FIG. 6 illustrates a preferred format of the variable-length parameters 60, as defined by the message type 54. The variable-length parameters contained in a message are defined in the parameter tag 61, parameter length 62, and parameter value 63 fields.

The parameter tag field 61 is preferably a 16-bit unsigned integer, and identifies the type of parameter. It preferably takes a value of 0 to 65534. The value of 65535 is reserved for Internet Engineering Task Force (IETF)-defined extensions. Values other than those defined in specific parameter description are reserved for use by the IETF. The parameter tags are shown in Table 5.

TABLE 5

| | |
|---|---|
| 0 | Reserved |
| 1 | Interface Identifier |
| 2 | Master/Slave Indicator |
| 3 | M2TP-User Identifier |
| 4 | Info String |
| 7 | Diagnostic Information |
| 9 | Heartbeat |
| 10 | Reason |
| 12 | Error Code |
| 13 | Protocol Data |
| 14 to 65534 | Reserved by the IETF |

The parameter length field 62 is preferably a 16-bit unsigned integer. The parameter length field 62 contains the size of the parameter in bytes, including the parameter tag field 61, parameter length field 62, and parameter value field 63. Thus, a parameter with a zero-length parameter value field would have a length field of 4. The parameter length field 62 does not include any padding bytes.

The parameter value field 63 has a variable length, and preferably contains the information to be transferred in the parameter. The total length of a parameter (including tag, parameter length, and value fields) is preferably a multiple of 4 bytes. If the length of the parameter is not a multiple of 4 bytes, the parameter is padded at the end (i.e., after the parameter value field) with all zeros. The length of the padding is not included in the parameter length field 62. Preferably, padding never exceeds 3 bytes, and is ignored by the destination side.

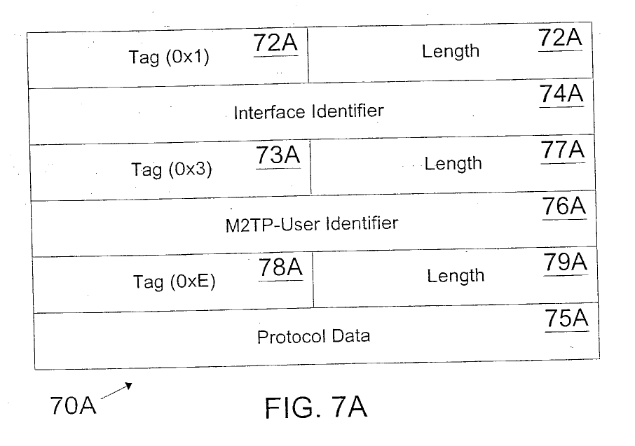

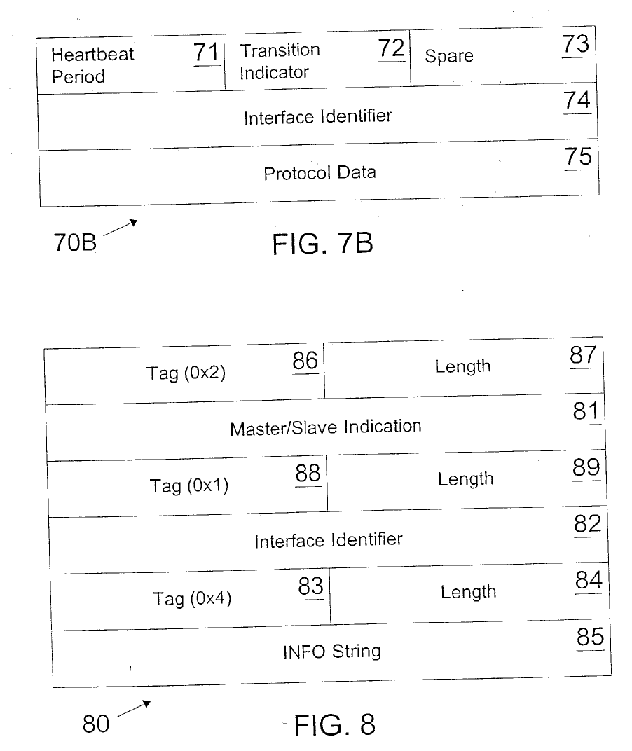

FIGS. 7A-11 show the various types of M2TP messages that can be formed. These messages include User Data Messages, MTP-2 user Adaption Message (MAUP) messages, Signaling Gateway Maintenance (SGM) messages, and layer management (MGMT) messages. Each M2TP message preferably uses the common message header 50 of FIG. 5.

FIG. 7A shows a preferred embodiment of a data message 70A, which is used to carry a SS7 MTP-2 Data message. The data message 70A preferably contains a M2TP-User Identifier parameter 76A, an Interface Identifier parameter 74A, and a Protocol Data parameter 75A. It is noted that the Protocol Data parameter 75A preferably comes last in order to facilitate efficient transfer of the protocol data.

The Interface Identifier parameter 74A identifies the physical interface at the SG for which the signaling messages are sent/received. The format of the Interface Identifier parameter is an integer, the values of which are assigned according to network operator policy. The values used are of local significance only, coordinated between the peer SG's. The M2TP-User Identifier parameter 76A identifies the user of the M2TP layer. The preferred values for the M2TP-User Identifier are shown in Table 6.

TABLE 6

| | |
|---|---|
| 0 | Reserved |
| 1 | MTP2 |
| 2 | Q.921 |
| 3 | Frame Relay |

The Protocol Data field 75A contains the MTP2 Protocol Data. The Protocol Data begins with the Forward Sequence Number (FSN), followed by the Backwards Sequence Number (BSN). Tag parameters 71A, 73A, 78A and Length parameters 72A, 77A, 76A may also be provided.

FIG. 7B illustrates the preferred format for a MAUP message. The MAUP message is preferably a data message 70A that contains a SS7 MTP-2 User Protocol Data Unit (PDU). The MAUP message is thus in the form of a PDU. As shown in FIG. 7A, the message preferably includes a heartbeat period parameter 71, a transition indicator parameter 72, an interface identifier parameter 74, and a protocol data parameter 75. The message also includes a spare parameter 73.

The interface identifier parameter 74 preferably identifies the physical interface at the SG 22, 26 where the signaling messages are sent and received. The interface identifier parameter 74 is an integer, the values of which are preferably assigned according to network operator policy. The values used are of local significance only, and are preferably coordinated between the peer SGs.

The transition indicator 72 is a Boolean value which preferably indicates whether the receiving SG 26 should update the default Signal Unit (SU), which the receiving SG 26 sends to its SEP 28. If the value of this field is non-zero, the receiving SG 26 updates its default SU with the SU in the protocol data field 75. If the value of this field is zero, the receiving SG 26 does not update its default SU.

The heartbeat period parameter 71 contains the maximum time period that is permitted to elapse between transmission of M2TP messages to the peer SG. The heartbeat period field indicates the current period of the heartbeat timer, preferably in milliseconds. The timer period appears in the MAUP message 70B so that the network operator may adjust the period without having to tear down the M2TP connection. The considerations used in adjusting the period are implementation specific.

The protocol data field 75 contains the MTP-2 user application message in network byte order.

FIG. 8 illustrates a preferred embodiment of a SGM message 80. The SGM message 80 is preferably sent by the SGs 22, 26 at each end of the SS7 virtual link. The SGM message 80 exchange indicates whether the SG 22, 26 is a master or a slave for a given virtual link. Each SG 22, 26 maintains the state of the peer SG's capability to handle traffic for the SS7 virtual link.

The SGM messages preferably include a Signaling Gateway Up (SG-UP) message, a Signaling Gateway UP Acknowledge (SG-UP Ack) message, a Signaling Gateway Down (SG-DN) message, and a Signaling Gateway Down Acknowledge (SG-DN Ack) message. Additionally, a heartbeat acknowledge (BEAT Ack) message is also provided.

The SG-UP message is used by a SG to indicate to the M2TP peer SG that the adaptation layer is ready to receive traffic or maintenance messages for the given interface identifier 82. The SG-UP message preferably includes a Master/Slave Indication parameter 81 and an Interface Identifier 82. It may also optionally include an INFO string 65. The format and description of the interface identifier field 82 are the same as that of the interface identifier 74A in the data message 70A, above. The INFO string parameter 85 can carry any 8-bit ASCII character string along with the message. For example, it could be used for debugging purposes. The length of the INFO string parameter 85 ranges from 0 to 255 characters. The SG-UP message may also include a length parameter 83 and a tag parameters.

The SG-UP Ack message is used to acknowledge reception of a SG-UP message from a remote M2TP peer. The format and description of the parameters are the same as for the SG-UP message 80 as shown in FIG. 8.

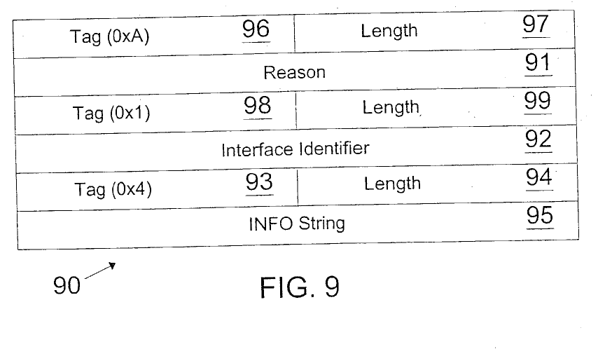

FIG. 9 illustrates a preferred format for the SG-DN message 90. The SG-DN message 90 indicates to a remote M2TP peer that the adaptation layer is not ready to receive traffic or maintenance messages for a given interface identifier. The SG-DN message preferably includes a Reason parameter 91 and an Interface Identifier 92. It may also optionally include an INFO string parameter 95. The message may further includes a tag parameters and a length parameters. The format and description of the interface identifier parameter 92 are the same as described in the data message 74A of FIG. 7A. The format and description of the INFO string parameter 95 are the same as described in the SG UP message (FIG. 8). The reason parameter 91 indicates the reason that the remote M2TP adaptation layer is unavailable. A value of 0×1 in the reason parameter 91 indicates that the reason is a management order.

The SG-DN Ack message is used to acknowledge receipt of a SG-DN message 90 received from a remote M2TP peer. The format of the SG-DN Ack message is the same as for the SG-DN message 90.

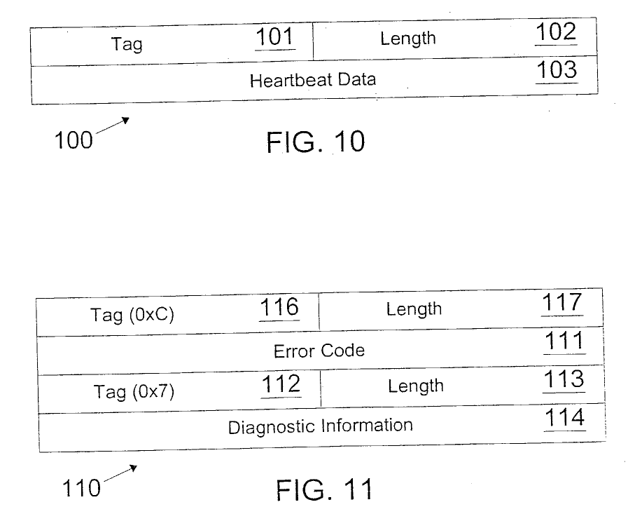

FIG. 10 illustrates a preferred embodiment of the BEAT heartbeat message 100. As shown in FIG. 10, the BEAT message preferably includes a tag parameter 101, a length parameter 102, and a heartbeat data parameter 103. The heartbeat data parameter 103 contents are preferably defined by the sending node. The heartbeat data could include, for example, a heartbeat sequence number and timestamp. The receiver of a heartbeat message 100 preferably does not process this field, as it is only of significance to the sender. The receiver responds with a BEAT-Ack message identical to the BEAT message.

The BEAT message 100 is used to ensure that the M2TP peers are available to each other. It may be used even when the transport layer is a SCTP (which has its own heartbeat mechanism), to provide a faster heartbeat than the heartbeat provided by the SCTP. In the absence of any other messages, the heartbeat message 100 is sent to the peer at a prescribed interval. Such an interval can specified by the Heartbeat Period parameter 71 of the data message 70B.

FIG. 11 illustrates a preferred format of the Layer Management (MGMT) Messages. Specifically, FIG. 11 illustrates an error message (ERR) 110. The ERR message 110 is used to notify a peer of an error event associated with an incoming message. For example, an error indication could be due to an unexpected message type 54 (FIG. 5) for the current state, a master/slave mismatch, or an interface identifier mismatch. It can also occur when a parameter value 63 (FIG. 6) is invalid.

The ERR message 110 preferably contains an error code parameter 111, and may optionally include diagnostic information 114. The ERR message 110 may also include a Tag Parameter 112 and a Length Parameter 113

The error code parameter 111 indicates the reason for the error message 110. Table 7 provides the preferred error codes.

TABLE 7

| Description | Value |
|---|---|
| Invalid Version | 0 × 1 |
| Invalid Interface Identifier | 0 × 2 |
| Invalid Adaptation Layer Identifier | 0 × 3 |
| Invalid Message Type | 0 × 4 |
| Invalid Traffic Handling Mode | 0 × 5 |
| Unexpected Message | 0 × 6 |
| Protocol Error | 0 × 7 |
| Invalid Stream Identifier | 0 × 8 |
| Incompatible Master/Slave Configuxation | 0 × 9 |

The optional diagnostic information parameter 114 can be used to provide any information pertinent to the error condition to assist in identification of the error condition. For example, in the case of an invalid version error code, the diagnostic information may include the supported version parameter. In other cases, the diagnostic information parameter 114 may contain the first 40 bytes of the offending message. In the case of an incompatible interface identifier code, the proper interface identifier code is preferably provided.

The M2TP protocol, as described above, can provide various services on a common channel communication system. Some of these services will next be described.

The M2TP protocol can provide MTP-2 message filtering and suppression. Referring to FIG. 3B, the slimmed-down MTP-2 layer 12b at the SG examines specific components of each SS7 message and determines whether the message should be forwarded to the peer SG, or instead filtered and discarded. Thus, when the originating SG 22 receives two or more identical SS7 messages in direct succession for a given interface ID, the SG preferably does not transmit the second and subsequent messages to the peer SG 26. Any succession of identical messages for a given interface ID preferably results in the transmission of one initial message to the peer SG 26 and subsequent, periodic heartbeat messages to confirm that the transmitting SG 22 is still operational. Thus, as used herein, a Transitional Message is a message which differs in content from the previous message. This includes differences in Forward Sequence Number (FSN), Backward Sequence Number (BSN), Forward Indicator Bit (FIB), Backward Indicator Bit (BIB), or Link Status Signal Unit (LSSU) type in addition to the Message Signal Unit (MSU) content.

The next service is message generation. When no messages are being received from the originating SG 22, the destination SG 26 transmits a continuous stream of the default SUs to its SEP 28. This continuous transmission of SUs ensures that there is no gap in the transmission of packets on the SS7 link segment. This conforms to the requirements of the MTP-2 protocol. The default SU may be updated via the transition indicator field 72 of the data message 70B (FIG. 7B) or in any other method.

M2TP also provides message forwarding. For this service, an originating SG 22 forwards a SS7 SU received from its SEP 20 to the appropriate peer SG 26 if the message arrives from the SEP error-free, and the message is a MSU or is different from the immediately preceding message.

Thus any MTP-2 state transition will trigger the SG to forward the first Link Status Signal Unit (LSSU) in the state transition since it will necessarily be different from the message immediately preceding it. This, consequently, provides for immediate forwarding of information on MTP-2 state transitions.

Such MTP-2 state transitions will most often consist of alignment procedures, including both progression and regression. For instance, if a SG 22 detects a transition from receipt of a Status Indication Out of Service (SIOS) to receipt of Service Information Octet (SIO), the SG 22 forwards to its peer SG 26 an indication of SIO when it first detects the change, followed by periodic heartbeat messages. The MTP-2 protocol data 75 is not modified by either SG 22, 26.

The next service is MTP-2 message proxying. In this service, the SG determines the current state of the remote SS7 link based upon M2TP messages received from its peer. The MTP-2 messages transmitted to the SEP by the local MTP-2 layer determines the state of the remote SS7 link. In many situations, for example, during alignment procedures and between MSUs, the local MTP-2 layer preferably transmits a string of identical messages. This would mirror the role of the filtering function. Namely, a stream of identical SS7 messages from the SEP is converted by the SG into one or more M2TP messages. These M2TP messages are then converted back into a stream of SS7 messages to the SEP.

If a SG has finished transmitting a MSU to the corresponding SEP but has not yet received the next signaling unit from its peer SG, then the SG preferably commences transmitting a stream of FISUs with FSN and BSN configured to match that of the preceding MSU.

Another service is the SS7 Link Error Condition. According to this service, if error rates are sufficiently high to trigger either AERM or SUERM, then the MTP-2 function in the SG will take the link out of service and initiate transmission of a Status Indicator Out of Service (SIOS) message to the local SS7 SEP. Immediately thereafter, the local SEP will respond with SIOS. In response, the SG will forward the SIOS to the remote SEP through the message forwarding mechanism, as indicated above.

By comparison, a real, single-link SS7 configuration would cause the remote SEP to take the link out of service through its local detection of excessive errors. In contrast, the process described herein relies upon the remote SEP to receive and ultimately transmit SIOS. The time required for this process is on the order of milliseconds.

The next M2TP service is mapping. The M2TP layer 15 preferably maintains a map of an interface ID to a physical interface on the SG. A physical interface could include, for example, a V.35 line, a T1 line/timeslot, or a E1 line/timeslot. The M2TP layer also maintains a map of interface identifier-to-SCTP association and to the related stream within the association.

Next, M2TP provides flow control and congestion services. Thus, the M2TP layer 15 may be informed of packet network congestion, for example IP network congestion, by an implementation-dependent function (i.e., an indication from the SCTP). If the M2TP layer 15 receives this indication, the action taken is implementation dependent. For example, the Slim MTP-2 12b on the SG could autonomously inject Status Indication Busy (SIB) signals into the traffic stream to the remote SEP.

SCTP stream management is another service provided by M2TP. SCTP allows a user a specified number of streams to be opened during the initialization. The M2TP layer 15 ensures proper management of these streams. SCTP streams provide for avoidance of head-of-line blocking. For that reason, a separate stream is preferably used for each SS7 virtual link segment between two SGs. The SS7 signaling link can be identified by the interface identifier in the data message header 50 (FIG. 5).

Finally, M2TP provides seamless SS7 network management interworking and active association control. Thus, if the SG loses the SCTP association to its mated SG, the SC preferably takes the link out of service and sends a M-SCTP release indication to the network management layer. Additionally, an indication of the status of the destination SG is maintained by the originating SG. Multiple such SG statuses need to be maintained, one for each SS7 virtual link segment supported by the SG. The M2TP does not support load-sharing or fail-over procedures.

Next, procedures used to support management of active associations between SG's will be described. As used herein, Layer Management is a function in the SG that. handles the inputs and outputs between the M2TP layer and a local management entity. Also, the Master SG is the SG responsible for the setting up of the SCTP association between the mated SGs for each SS7 virtual link. The concept of a master SG is only relevant on a given SS7 virtual link. This implies that a SG might act as a master SG for certain SS7 virtual links and as a slave SG for others. Mated SG refers to a pair of SGs which are connected through a SS7 virtual link segment to provide the appearance of an end-to-end SS7 link to two SEPs. Finally, a slave SG is responsible for receiving the request to initiate a SCTP association that is sent by the master SG. The concept of a slave SG is only relevant on a given SS7 virtual link.

Before the establishment of an SCTP association, the SG state (i.e., the SS7 virtual link state) at both mated SGs is assumed to be “down.”

The master SG 22 for the given SS7 virtual link segment initiates the setup of an SCTP association with the slave SG 26. When the master SG 22 receives an M-SCTP Establish Request primitive from the layer management, the master SG 22 attempts to establish an SCTP association with the slave SG 26. Upon reception of an eventual SCTP-Communication Up Confirm primitive from the SCTP, the master SG 22 invokes the primitive M-SCTP Establish Confirm to the layer management.

At the slave SG 26, the M2TP layer 15 will receive an SCTP Communication Up Indication primitive from the SCTP. The slave SG 26 then invokes the primitive M-SCTP Establish Indication to the layer management.

Once the SCTP association has been established, the local SGM function will initiate the SGM procedures, using the SGM messages 80 (FIG. 8) to convey the SG state to the peer SG.

The layer management and the M2TP layer 15 on the SG can communicate the status of the peer SG using the M-SG Status primitives. The layer management and the M2TP layer 15 can communicate the status of an SCTP association using the M-SCTP Status primitives.

If the layer management wants to bring down a SCTP association for management reasons, it would send a M-SCTP Release Request primitive to the local M2TP layer 15. The M2TP layer 15 would release the SCTP association, and upon receiving the SCTP Communication Down indication from the underlying SCTP layer 16, it would inform the local layer management using M-SCTP Release Confirm primitive.

If the M2TP layer 15 receives a SCTP-Communication Down indication from the underlying SCTP layer 16, it will preferably inform the layer management by invoking the M-SCTP Release Indication primitive. The state of the SG will be moved to “down” at both the local SG and the peer SG, for the given interface identifier.

At the master SG 22, the layer management may try to reestablish the SCTP association using M-SCTP Establish Request primitive.

Upon receipt of an error message 110 from the peer, the MTP-2 User Adaptation (M2UA) layer (not shown) invokes the corresponding layer management primitive (M-ERROR) to the local layer management.

If the layer management wants a SG to be removed from the configuration for management reasons, it would send a M-SG-DOWN Request primitive to the SG. This primitive requests the SG to stop its operation and send a SG-DOWN message to the peer SG.

If the Layer Management wants a SG to be added to the configuration for management reasons, it would send a M-SG-UP request primitive to the SG. This primitive requests the SG to send a SG-UP message to its peer SG.

Whenever a peer=s status changes, the SG preferably sends a M-SG Status indication to the layer manager.

The procedures for supporting peer-to-peer messages will next be described.

All SGM messages 80 (FIG. 8) are sent on a sequenced stream to ensure ordering. Preferably, SCTP stream 0 is used.

After an SCTP association has been successfully established between the virtual link segments, the slave SG 26 waits for the master SG 22 to send a SG-UP message, indicating that the master SG 22 M2TP peer is available. When the SG-UP message is received at the slave SG 26, and internally the master SG 22 is not considered locked-out for local management reasons, the slave SG 26 marks the peer SG 22 as “up.” The slave SG 26 responds with a SG-UP Ack message in acknowledgment. The slave SG 26 sends an SG-UP Ack message in response to a received SG-UP message even if the peer SG 22 is already marked as “up”.

If for any local reason (for example, a management lock-out) the slave SG 26 cannot respond with a SG-UP Ack, the slave SG 26 responds to a SG-UP with a SG-DOWN Ack message with a reason of “management blocking.” Upon reception of the SG-DOWN Ack message, the master SG 22 will preferably resend the SG-Up message.

At the master SG 22, the SG-UP Ack message received from the slave SG 26 is not acknowledged by the master SG 22. If the master SG 22 does not receive a response from the slave SG 22, or if a SG-DOWN message is received, the master SG 22 may resend the SG-UP messages every two seconds until it receives a SG-UP Ack message from the slave SG 26. The master SG 22 may decide to reduce the frequency (to, for example, every 5 seconds) if a SG-UP Ack message is not received after a prescribed number of tries.

Data messages 70A do not flow between a mated SG pair until a SG-UP/SG-UP ACK sequence of messages has been exchanged between the pair. If a SG receives a data message 70A from its peer or a Send Data primitive from its NIF 34, 35 before a SG-UP or SG-UP Ack is received, the SG discards it.

The SG will preferably send a SG-DOWN message to its peer when the sending SG is to be removed from the configuration for the given interface identifier. The receiver marks the sender as “down” and returns a SG-DOWN Ack message to the peer if a SG-DOWN message is received from the peer, or if another SGM message 80 is received from the peer and the SG has locked out the peer for management reasons.

The SG sends an SG-DOWN Ack message in response to a received SG-DOWN message from the peer, even if the peer is already marked as “down” at the SG.

If the SG does not receive a response from the peer, the SG may send a SG-DOWN messages every two seconds until it receives a SG-DOWN Ack message from the peer or the SCTP association goes down. The SG may decide to reduce the frequency (to, for example, every 5 seconds) if a SG-DOWN Ack is not received after a prescribed number of tries.

On receipt of this message, the receiving SG preferably initiates the release of the local SS7 link segment, and preferably informs the layer manager, if the peer's status was up. The SG sending the SG-DN message initiates the release of its local SS7 link segment. The release preferably causes LSSUs of type SIOS to be sent to the remote SEP.

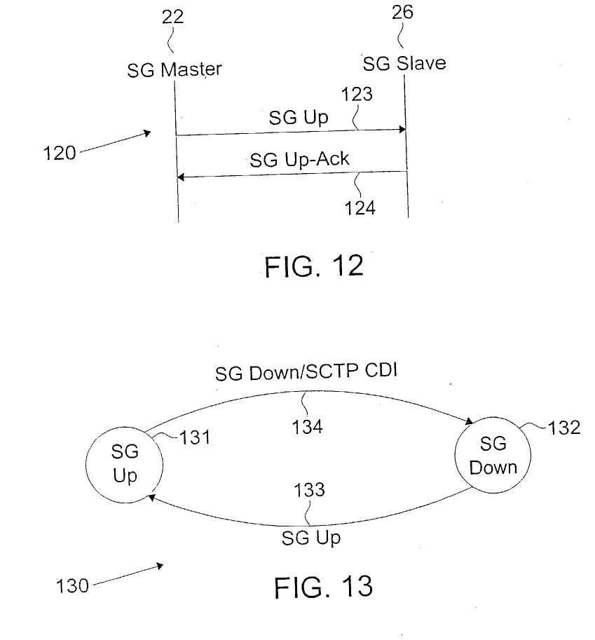

FIG. 12 illustrates a M2TP message flow for the establishment of traffic between two mated SGs 22, 26 according to the preferred embodiment. The master SG 22 sends a SG UP message 123 to the slave SG 26. The slave SG 26 responds by returning a SG UP Ack message 124 to the master SG 22. It is understood that the SCTP association has already been set up, having been initiated by the master SG 22.

FIG. 13 illustrates state maintenance procedures, according to the preferred embodiment. The SG preferably maintains the state of each of its peer SG's for each SS7 virtual link segment. As shown in FIG. 13, the state machine is maintained at each SG for each of its peers and for each SS7 virtual link segment. Initially the peer is assumed to be in the SG-DOWN state 132. When an SG UP message 133 is received from the peer SG, the state machine corresponding to the peer SG transitions to the SG-UP state 131. The SG-UP state 131 remains active until the corresponding peer SG sends an SG-DOWN or SCTP CDI message 134.

Next, procedures to support declaring a SS7 link to be down will be described. Thus, M2TP may initiate corrective procedures when a SCTP communication failure is indicated by non-reception of the M2TP heartbeat message 100 at the SG.

A timer may be maintained at each SG to determine if the corresponding SEP must be informed that the SS7 signaling link is down. The timeout value for this timer is preferably configured at each SG as

T=(N*P)+R Equation 1

where

T=Timeout value;

N=Number of consecutive missing heartbeat message periods to wait before declaring the SS7 link to be down, N preferably is between 1 and 3;

P=Heartbeat period; and

R=Worst case transit delay of the network.

Finally, it is noted that M2TP can also provide security. M2TP is designed to carry signaling messages for telephony services. As such, M2TP must involve the security needs of several parties. These parties include the end users of the services, the network providers, and the applications involved. Additional requirements may come from local regulation. While having some overlapping security needs, any security solution preferably fulfills all of the different parties' needs.

As a transport protocol, M2TP has the following security features. First, it provides reliable and timely user data transport. Next, it maintains integrity of user data transport. Additionally, it provides confidentiality of user data.

M2TP preferably runs on top of SCTP. SCTP provides certain transport related security features, such as blind denial of service attacks, flooding, masquerade, and improper monopolization of services. When M2TP is running in a professionally managed corporate or service provider network, it is reasonable to expect that such a network would include an appropriate security policy framework.

When the network in which M2TP operates involves more than one party, it may not be reasonable to expect that all parties have implemented security in a sufficient manner. In such a case, it is recommended that IPSEC be used to ensure confidentiality of user payload.

Particularly for mobile users, the requirement for confidentiality may include the masking of IP addresses and ports. In this case, application level encryption is not sufficient; IPSEC Encapsulating Security Payload (ESP) should preferably be used instead. Regardless of which level performs the encryption, the IPSEC Internet Security Association and Key Management Protocol (ISAKMP) service is preferably used for key management.

A request will be made to Internet Assigned Numbers Authority (IANA) to assign a M2TP value for the payload protocol identifier in a SCTP payload data chunk. The SCTP payload protocol identifier is included in each SCTP data chunk to indicate which protocol the SCTP is carrying. This payload protocol identifier is not directly used by SCTP, but may be used by certain network entities to identify the type of information being carried in a data chunk.

The user adaptation peer may use the payload protocol identifier as a way of determining additional information about the data being presented to it by the SCTP.

The M2TA and slim MTP-2 protocol of the preferred embodiment provide for the tunneling of MTP packets through a packet switched network. There is no buffering of MSUs in transmission or re-transmission queues of the SG. All buffering within the slim MTP-2 is done within the device driver or within queues that are associated with particular processes. As a result, there is no retrieval of MSUs. Retrieval is done at the end points of the SS7 links.

As described herein, the preferred embodiment has many advantages. For example, it increases the efficiency of circuits used to communicate the SS7 signaling information between SEPs. This increased efficiency is achieved by integrating SGs within a SS7 link to support the transport of SS7 signaling with a packet switched network over a significant portion of the communication link between the SEPs.

Additionally, the two SGs acting in tandem provide the appearance of a single signaling link to the MTPs at both ends. To do this, the SGs repeat the transmissions of the MTP-2 protocol to the SS7 SEPs. The SGs also filter, modify, and duplicate these transmissions as necessary. The MTP-2 functions within the SG are a slimmed down version of the full MTP-2 and provide for the forwarding of MTP-2 Signal Units, except those that are redundant. When a SU is received, it indicates a transition on the link which is then mirrored by the mated SG. The slimmed down MTP-2 provides support for the Alignment Error Rate Monitor (AERM) and Signal Unit Error Rate Monitor (SUERM) functions, as it is not feasible or necessary to transport errant SUs through the IP network. The concept of a slimmed down MTP-2 allows for the MTP-3 implementations at each signaling end point to perform unmodified.

Additionally, SS7 signaling messages can be transported over packet switched networks without modifying or reconfiguring the existing network. This is because the SGs have no point codes. Thus, the SPs do not need to be reconfigured to recognize new point codes.

Also, the existing SPs do not need to be replaced by IP equipment.

Moreover, because no point codes are required, there is no delay caused by waiting for a point code assignment.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A method for performing MTP-2 message proxying, comprising:
generating a message indicative of a current state of an SS7 link coupled to a first gateway;
sending the message to a second gateway over a packet-switched network; and
transmitting data from the second gateway to the first gateway over the packet-switched network based on the message.

2. The method of claim 1, wherein the message is an M2TP message.

3. The method of claim 1, further comprising:
determining, in the second gateway, the current state of the SS7 link based on the message.

4. The method of claim 1, further comprising:
sending a plurality of identical SS7 messages from a signaling point to the first gateway;
converting the SS7 messages into M2TP messages;
converting the M2TP messages back into SS7 messages;
sending the converted SS7 messages back to the signaling point; and
generating the message indicative of the current state of the SS7 link based on the converted SS7 messages.

5. The method of claim 4, wherein the message is an M2TP message.

6. A method for detecting errors in a communications link, comprising:
detecting an error condition in an SS7 link; and
transmitting an M2TP control message to a first gateway coupled to the SS7 link, said first gateway removing the SS7 link from service based on the detected error condition.

7. The method of claim 6, wherein the detecting step includes:
detecting the error condition based on whether error rates reach a value sufficient to trigger at least one of an AERM and an SUERM.

8. The method of claim 6, further comprising:
transmitting an out-of-service message to a signaling point connected to the SS7 link.

9. The method of claim 8, further comprising:
transmitting the out-of-service message from the signaling point to a second gateway though the first gateway, said second gateway coupled to the first gateway by a packet-switched network.

10. The method of claim 9, wherein in the transmitting step, the out-of-service message is transmitted to the second gateway in M2TP format.

11. A method for filtering signals in a communications system, comprising:
receiving first and second SS7 messages in succession;
comparing the first SS7 message to the second SS7 message; and
filtering one of the first and second SS7 messages based on a result of the comparison.

12. The method of claim 11, wherein the filtering step includes:
filtering the second SS7 message if a result of the comparison indicates that the second SS7 message is identical to the first SS7 message.

13. The method of claim 11, wherein the filtering step includes:
filtering the second SS7 message if the first and second SS7 messages include same information.

14. The method of claim 13, wherein said same information includes a same Message Signal Unit (MSU) content as well as at least one of the following: Forward Sequence Number (FSN), Backward Sequence Number (BSN), Forward Indictor Bit (FIB), Backward Indicator Bit (BIB), or Link Status Signal Unit (LSSU).

15. The method of claim 12, further comprising:
converting the first SS7 message to a Layer 2 message; and
sending the Layer 2 message over a communications link.

16. The method of claim 15, wherien the communications link is an IP link.

17. The method of claim 15, wherein at least converting step is performed in a signaling gateway connecting a circuit-switched network to a packet-switched network which includes said communications link.

18. The method of claim 17, further comprising:
sending at least one heartbeat message over the communications link to confirm that the gateway is operational, said at least one heartbeat message being sent after the Layer 2 message is sent over the communications link.

19. The method of claim 15, wherien the receiving step includes receiving the first and second SS7 messages from a circuit-switched network, and wherein said communications link is included in a packet-switched network.

20. The method of claim 19, wherein the Layer 2 message is an M2TP-formatted message.

21. The method of claim 20, wherein the M2TP-formatted message conforms to an SCTP signaling protocol.

22. A method for managing a communications link between two gateways, comprising:
determining whether a first gateway received a signal from a second gateway within a predetermined period of time;
if not, transmitting a stream of default signal units from the first gateway to the second gateway to ensure that no gap in transmission of packets occurs on an SS7 link connected to one of the first gateway and second gateway, wherein the communications link is included in a packet-switched network and the default signal units ate M2TP-formatted signal units.

23. The method of claim 22, wherein the transmitting step includes transmitting the default signal units at a frequency which conforms to MTP-2 protocol requirements.

24. A method for managing a communications link between two gateways, comprising:
determining, in a first gateway, whether an SS7 signal unit is received from a signaling point error-free; and
if received error-free, converting the SS7 signal unit into at least one M2TP-formatted data packet and transmitting the at least one data packet over the communications link to a second gateway.

25. The method of claim 24, wherein the converting and transmitting steps are performed if the SS7 signal unit is different from an immediately preceding SS7 signal unit received from the signaling point or if the SS7 signal unit is an MSU.

26. The method of claim 24, further comprising:
detecting, in the first gateway, a state transition between the SS7 signal unit and an immediately preceding SS7 signal unit; and
sending information indicative o the state transition to the second gateway.

27. A method for monitoring status of a communications link, comprising:
providing a signaling gateway between a first network and a second network, said signaling gateway including a converter which converts SS7 signaling data received from the first network to M2TP-formatted data for transmission over the second network; and
maintaining a map of an interface unit in the signaling gateway to a physical interface.

28. The method of claim 27, further comprising:
maintaining a map of an interface identifier-to-SCTP association and to related streams within the association.

29. A method for managing a communications link connecting two gateways, comprising:
receiving, in a first gateway, information indicative of congestion in a packet-switched network; and
inserting at least one status indication busy signal into a traffic stream carried by the communications link to a second gateway, wherein the status indication busy signal has an M2TP format.

30. A method for performing stream management in a communications system, comprising:
opening an SCTP stream for each of a plurality of SS7 virtual links between two signaling gateways; and
managing data carried over these streams using an M2TP layer.

31. A communications management method, comprising:
determining whether a first signaling gateway has lost an SCTP association to a second signaling gateway, said first signaling gateway converting SS7 data into M2TP-formatted data for transmission to the second signaling gateway; and
if the SCTP association is determined to be lost, removing a link between the first and second signaling gateways and sending an M-SCTP release indication information to a network management layer.

32. The method of claim 31, further comprising:
monitoring in the first signaling gateway a status of operation of the second signaling gateway.
